(19) United States
(12) Patent Application Publication
(10) Pub. No.: US 2026/0060106 A1
(43) Pub. Date: Feb. 26, 2026

(54) PACKAGE SUBSTRATE AND MANUFACTURING METHOD THEREOF

(71) Applicant: AaltoSemi Inc., Nanjing City (CN)

(72) Inventors: Min-Yao CHEN, Nanjing City (CN); Yin-Ju CHEN, Nanjing City (CN); Andrew C. CHANG, Nanjing City (CN)

(73) Assignee: AaltoSemi Inc., Nanjing City (CN)

(21) Appl. No.: 19/301,114

(22) Filed: Aug. 15, 2025

(30) Foreign Application Priority Data
Aug. 20, 2024 (CN) 202411141517.2

(51) Int. Cl. H01L 23/498; H01L 21/48

(52) U.S. Cl. CPC H01L 23/49827; H01L 21/486; H01L 23/49838

(57) ABSTRACT

Provided are a package substrate and a manufacturing method thereof. The package substrate includes a core board body, a first insulating layer, a circuit structure, and a wiring structure. The core board body is formed with openings connecting two opposite sides of the core board body. The first insulating layer is formed on the two opposite sides of the core board body and filled into the openings. Through holes are formed in the first insulating layer of the openings and are connected to surfaces of the first insulating layer on the two opposite sides of the core board body. The circuit structure includes a circuit layer formed on the surfaces of the first insulating layer on the two opposite sides of the core board body, and conductive pillars formed in the through holes and electrically connected to the circuit layer. The wiring structure is formed on the circuit structure.

### CROSS-REFERENCE TO RELATED APPLICATIONS

This application claims priority to Chinese Application No. 202411141517.2 filed on Aug. 20, 2024. The entirety of the above-mentioned patent application is hereby incorporated by reference herein and made a part of this specification.

### BACKGROUND

### 1. Technical Field

The present disclosure relates to a semiconductor packaging technology, and more particularly, to a package substrate and a method of manufacturing the same which can comply with high density and fine circuits.

### 2. Description of Related Art

With the booming development of portable electronic products in recent years, all kinds of related products are gradually progressing towards the trend of high density, high performance and being light, thin, short and small, and all kinds of packaging processes are also in line with the innovation, in order to meet the requirements of high density and being light, thin, short and small, such as high-density through hole methods.

FIG. 1A to FIG. 1F are schematic cross-sectional views showing a conventional manufacturing method of a package substrate 1 according to the prior art.

As shown in FIG. 1A, a core board body 10 made of a highly rigid material (such as glass) is provided and has a first side 10a and a second side 10b opposite to the first side 10a. Further, a first insulating layer 11, such as an Ajinomoto build-up film (ABF), is formed on the first side 10a and the second side 10b of the core board body 10 by lamination.

As shown in FIG. 1B, a plurality of through holes 100 penetrating through the core board body 10 and the first insulating layer 11 are formed to connect surfaces of the first insulating layers 11 of the first side 10a and the second side 10b of the core board body 10.

As shown in FIG. 1C, copper is plated on the surfaces of the first insulating layers 11 and the surfaces of the plurality of through holes 100 to form a plurality of conductive pillars 132 in the plurality of through holes 100, and a patterning process is carried out on the first insulating layers 11 on both opposite sides of the core board body 10 so as to form a circuit layer 131 on each side of the core board body 10, wherein the plurality of conductive pillars 132 are electrically connected to the circuit layer 131 to form a circuit structure 13.

As shown in FIG. 1D, a wiring structure 14 is formed on the circuit structure 13. The wiring structure 14 includes at least one wiring layer 141, at least one second insulating layer 142, and a plurality of conductive blind vias 143 formed in the second insulating layer 142 and electrically connected to the wiring layer 141 and the circuit structure 13.

As shown in FIG. 1E, a solder resist layer 15 is formed on the wiring structure 14, and a portion of the wiring layer 141 is exposed from the solder resist layer 15.

FIG. 1F shows a schematic top view of the conventional package substrate 1 after the first insulating layers 11 and the through holes 100 are formed. In a conventional manufacturing method, the through holes 100 are a plurality of individual holes drilled through the core board body 10 and the first insulating layers 11.

However, the through-hole manufacturing method of the conventional package substrate 1 limits the ability to manufacture fine through holes. For example, the through-hole manufacturing method of the conventional package substrate 1 cannot manufacture small aperture diameter through holes of less than 60 μm, and is not conducive to making the fine line and high density of the package substrate.

Moreover, due to the difficulty of localized formation of fine line width/line spacing (L/S) circuit (e.g., L/S=5/5 μm), the conventional manufacturing method cannot meet the requirements for forming high-density circuit structures, making it difficult to manufacture substrates to match the localized high-density flip-chip ball grid array (FCBGA) design.

Further, in the manufacturing method of conventional semiconductor packages, each of the through holes 100 can only be formed into a single size and shape, and the manufacturing method of the conventional semiconductor packages cannot meet the requirements of the local circuit layout for adjusting the aperture diameter of the through hole, and the through hole 100 may be formed in the form of a hole within a hole.

Therefore, how to overcome the various problems of the above-mentioned prior art has become an urgent issue to be solved.

### SUMMARY

In view of the various shortcomings of the prior art, the present disclosure provides a package substrate, which comprises: a core board body having a first side and a second side opposite to the first side and including a plurality of openings connecting the first side and the second side of the core board body; a first insulating layer formed on the first side and the second side of the core board body and filled into the plurality of openings, wherein a plurality of through holes are formed in the first insulating layer of the plurality of openings and are connected to surfaces of the first insulating layer on the first side and the second side of the core board body; a circuit structure including a circuit layer formed on the surfaces of the first insulating layer on the first side and the second side of the core board body, and a plurality of conductive pillars formed in the plurality of through holes respectively and electrically connected to the circuit layer; and a wiring structure formed on the circuit structure and including at least one wiring layer, at least one second insulating layer, and a plurality of conductive blind vias formed in the second insulating layer and electrically connected to the wiring layer and the circuit structure.

The present disclosure further provides a method of manufacturing a package substrate, and the method comprises: providing a core board body having a first side and a second side opposite to the first side; forming a plurality of openings connecting the first side and the second side of the core board body; forming a first insulating layer on the first side and the second side of the core board body and filling the first insulating layer into the plurality of openings; forming a plurality of through holes in the first insulating layer of the plurality of openings, wherein the plurality of through holes are connected to surfaces of the first insulating layer on the first side and the second side of the core board body; forming a circuit layer on the surfaces of the first insulating layer on the first side and the second side of the core board body, and forming a plurality of conductive pillars electrically connected to the circuit layer in the plurality of through holes, wherein the circuit layer and the plurality of conductive pillars constitute a circuit structure; and forming a wiring structure on the circuit structure, wherein the wiring structure includes at least one wiring layer, at least one second insulating layer, and a plurality of conductive blind vias formed in the second insulating layer and electrically connected to the wiring layer and the circuit structure.

In embodiments of the aforementioned package substrate and method, the core board body is made of glass, ceramic, silicon carbide, or a composite material with a modulus of 50 Gpa to 100 Gpa.

In embodiments of the aforementioned package substrate and method, the first insulating layer and the second insulating layer are each made of an Ajinomoto build-up film.

In embodiments of the aforementioned package substrate and method, the present disclosure further comprises: prior to forming the circuit structure, forming a barrier layer and a seed layer on the surfaces of the first insulating layer and surfaces of the plurality of through holes, wherein the barrier layer and the seed layer are located between the first insulating layer and the circuit structure.

In embodiments of the aforementioned package substrate and method, each of the plurality of openings has at least one shape independently selected from a group consisting of rectangular, square, circular and elliptical shapes.

In embodiments of the aforementioned package substrate and method, two or more of the plurality of through holes are formed in each single opening of the plurality of openings.

In embodiments of the aforementioned package substrate and method, the present disclosure further comprises: forming a solder resist layer on the wiring structure, wherein a portion of the wiring layer is exposed from the solder resist layer.

As can be seen from the above, in the package substrate and manufacturing method thereof of the present disclosure, large-size openings are first manufactured in a substrate, and small-size through holes are subsequently manufactured in the openings. Unlike the conventional manufacturing method of forming through holes in a substrate, the manufacturing method of the present disclosure is to form through holes in a first insulating layer in openings to manufacture conductive pillars, thereby greatly enhancing the capability of manufacturing small aperture diameter through holes and fine circuit structures and facilitating the development of high-density and high-precision package substrates.

Moreover, the package substrate of the present disclosure can be slotted in the area where high-density design is required locally, and fine line width/line spacing (L/S) circuits in the openings are subsequently manufactured to form a localized high-density circuit structure in conjunction with the FCBGA design, which is conducive to the high input/output (I/O) density of the advanced packaging, improves the efficiency in the utilization of space, and effectively promotes the miniaturization of the package structure.

Further, the manufacturing method of the present disclosure has high flexibility, and the openings can be selected in any shape such as rectangular, square, circular and elliptic according to the layout location, and the sizes of the openings and the aperture diameters of the through holes in the openings can be adjusted according to the circuit design to meet the needs of various packaging designs.

In addition, compared to the conventional manufacturing method which can only form a plurality of through holes of a single specification in the substrate, the present disclosure is to form a plurality of through holes in a single opening, allowing the specifications of the through-holes in different openings to be configured according to the local requirements, or the present disclosure can also form a plurality of through holes with the same or different aperture diameters in a single opening, thereby ensuring a high degree of flexibility in the design of the substrate and a wide range of adaptability at the packaging stage.

### BRIEF DESCRIPTION OF THE DRAWINGS

FIG. 1A to FIG. 1F are schematic cross-sectional views showing a conventional manufacturing method of a package substrate according to the prior art, where FIG. 1F is a schematic top view of the conventional package substrate after forming through holes.

FIG. 2A, FIG. 2B, FIG. 2C-1, FIG. 2D-1, FIG. 2E and FIG. 2F are schematic cross-sectional views showing a manufacturing method of a package substrate according to an exemplary first embodiment of the present disclosure.

FIG. 2C-2 and FIG. 2D-2 are partially enlarged schematic cross-sectional views showing the manufacturing method of forming a barrier layer and a seed layer according to the exemplary first embodiment of the present disclosure.

FIG. 2G is a schematic top view showing the package substrate after forming through holes according to the exemplary first embodiment of the present disclosure.

FIG. 3A to FIG. 3D are schematic cross-sectional views showing a manufacturing method of a package substrate according to an exemplary second embodiment of the present disclosure.

FIG. 3E is a schematic top view showing the package substrate after forming through holes according to the exemplary second embodiment of the present disclosure.

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, and should not be construed as limiting the conditions for practicing the present disclosure. Any modification of the structures, alteration of the ratio relationships, or adjustment of the sizes that do not affect the possible effects and achievable purpose of the techniques herein should still be deemed as falling within the scope of the disclosure as described by the technical content disclosed herein. Meanwhile, terms such as “on,” “in,” “inside,” “out,” “outside,” “a,” “one” and the like are merely used for clear explanation and are not limiting the practicable scope of the present disclosure, and thus, alterations or adjustments of the relative relationships thereof without essentially altering the technical content should still be considered as falling within the practicable scope of the present disclosure.

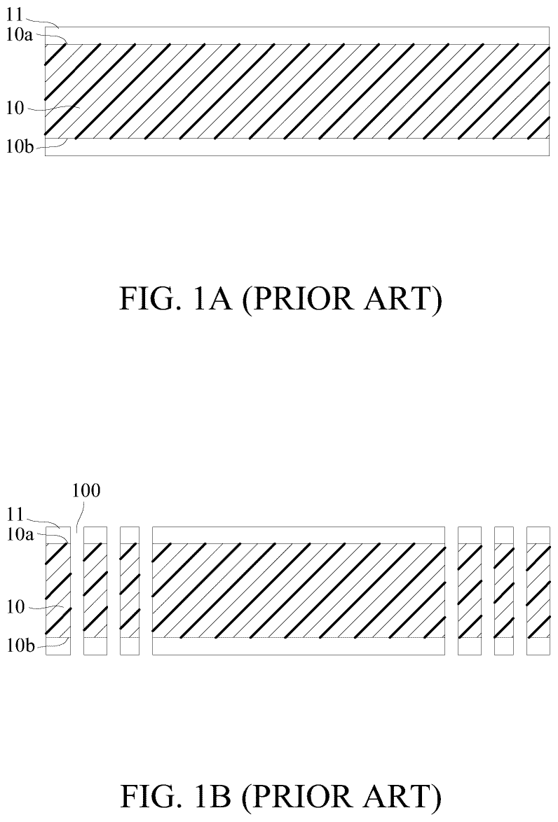

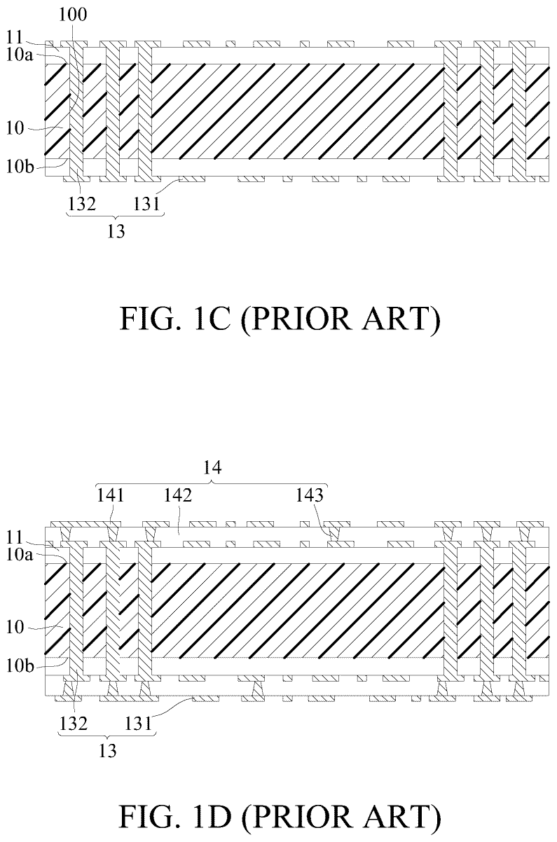

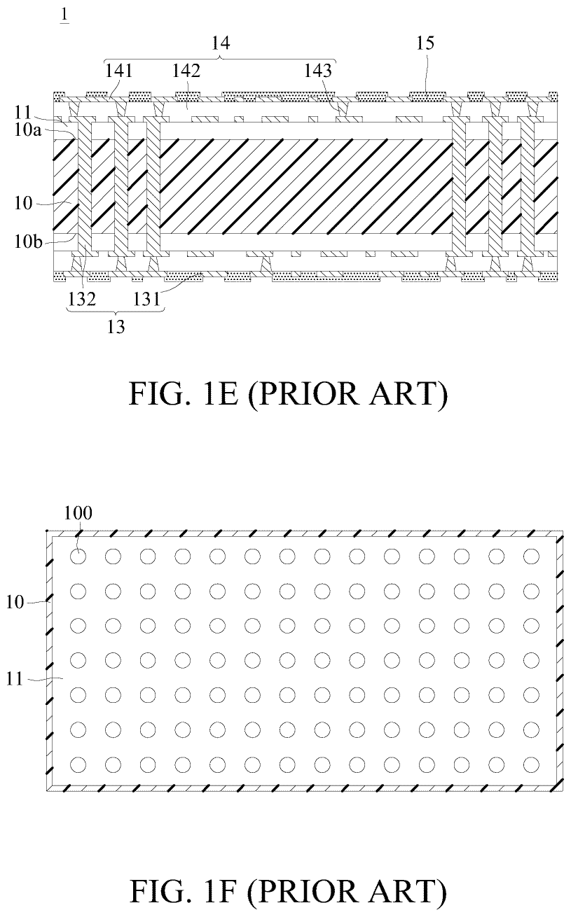

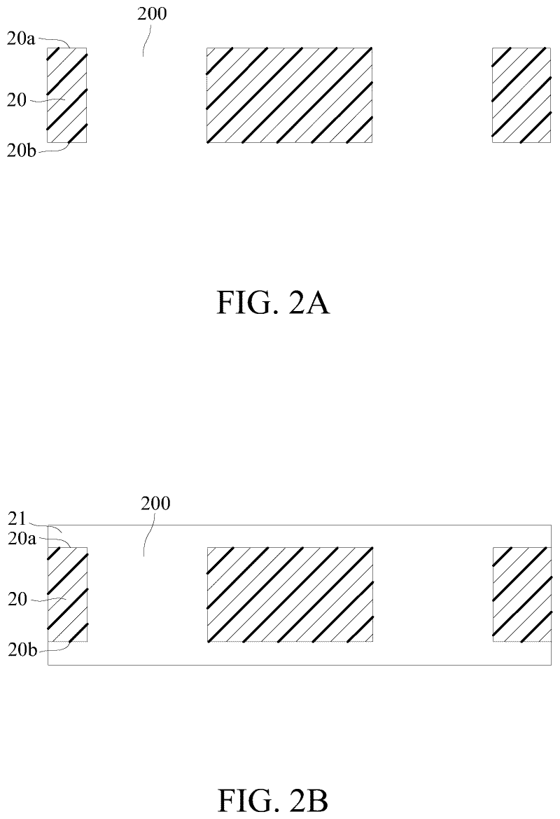

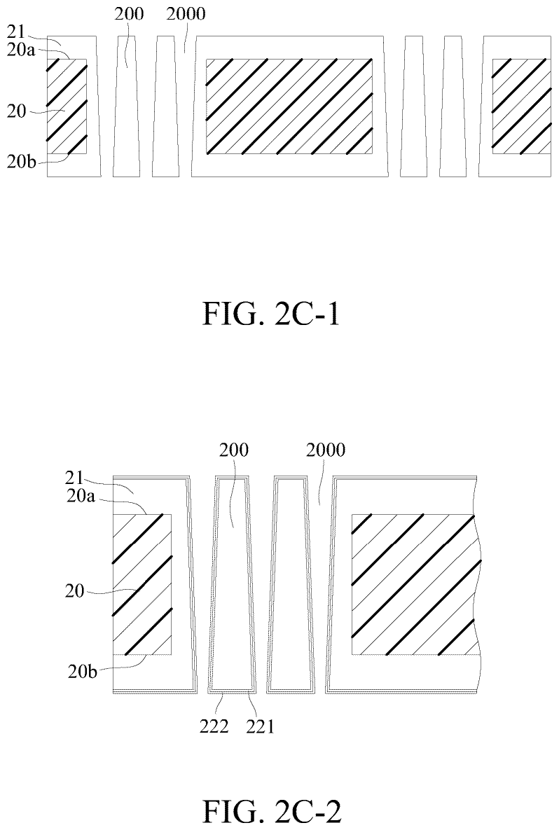

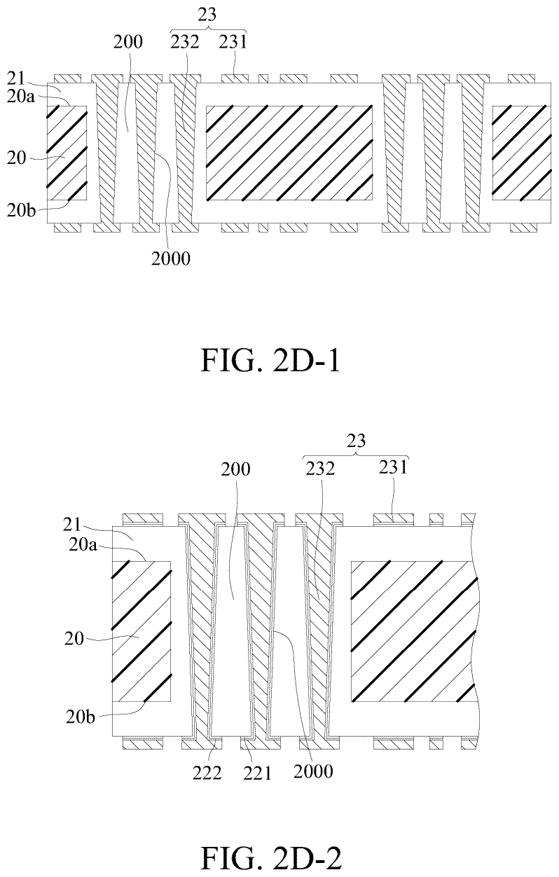

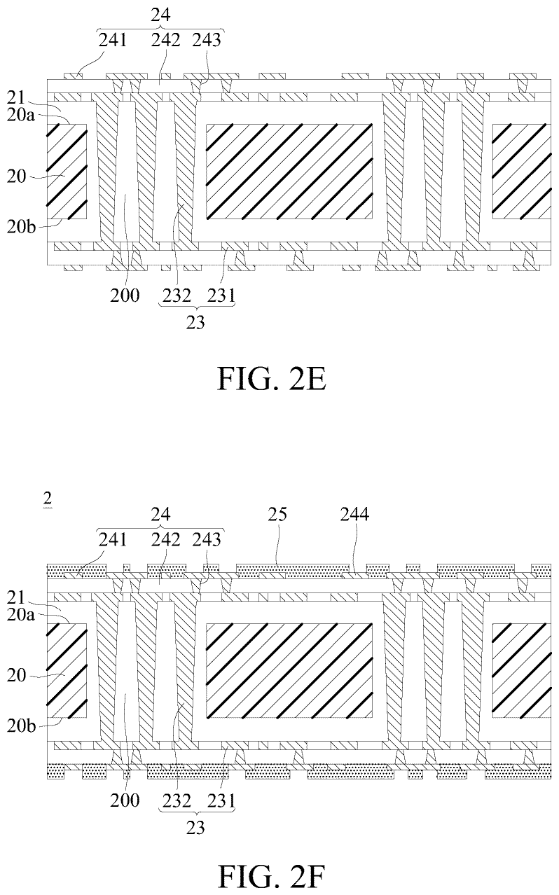

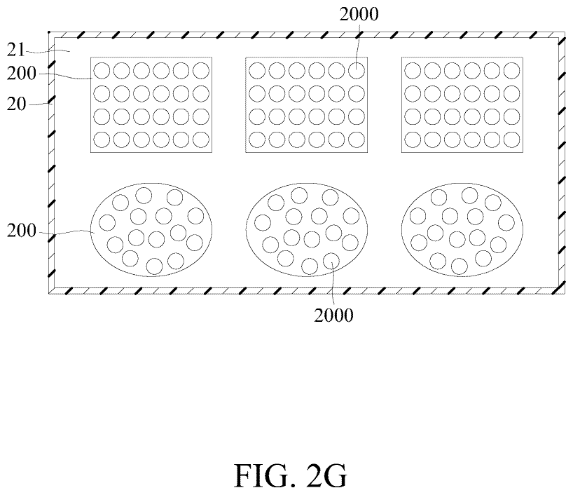

FIG. 2A, FIG. 2B, FIG. 2C-1, FIG. 2D-1, FIG. 2E and FIG. 2F are schematic cross-sectional views showing a manufacturing method of a package substrate 2 according to a first embodiment of the present disclosure.

As shown in FIG. 2A, a core board body 20 is provided. The core board body 20 has a first side 20a and a second side 20b opposite to the first side 20a, and a plurality of openings 200 connecting the first side 20a and the second side 20b of the core board body 20 are formed.

In an embodiment, the core board body 20 can be made of glass, ceramic, silicon carbide (SiC), a composite material with a modulus of 50 Gpa to 100 Gpa, or other highly rigid materials. The openings 200 can be formed by laser-induced or hydrofluoric acid (HF) etching, etc., and the shape thereof can be any shape such as rectangular, square, circular, elliptical, etc., but not limited thereto. The locations and sizes of the openings 200 can be selected according to the design requirements.

Further, the shapes and sizes of the plurality of openings 200 can be the same or different. For example, referring to the top view of FIG. 2G, the plurality of openings 200 are partly rectangular and partly elliptical.

As shown in FIG. 2B, a first insulating layer 21 is formed on the first side 20a and the second side 20b of the core board body 20, and the first insulating layer 21 is filled into the openings 200.

In an embodiment, the first insulating layer 21 can be made of an Ajinomoto build-up film (ABF) or other insulating materials. For example, the molten ABF covers the first side 20a and the second side 20b of the core board body 20 for build-up, and the openings 200 are filled with the ABF. After the ABF is cured, the first insulating layer 21 covering the two opposite sides of the core board body 20 and filled the openings 200 is formed.

The substrate made of high rigidity material such as glass may crack during the laser or etching process, however, an insulating material such as an ABF formed on the surfaces of the core board body 20 and in the openings 200 can prevent the cracks from expanding and damaging the substrate, such that the first insulating layer 21 is not only conducive to subsequent through-hole manufacturing, but also protects the structure of the substrate.

As shown in FIG. 2C-1, a plurality of through holes 2000 are formed in the first insulating layer 21 of the openings 200, and the plurality of through holes 2000 are connected to the surfaces of the first insulating layer 21 of the first side 20a and the second side 20b of the core board body 20, wherein the plurality of through holes 2000 can be formed by laser cauterization, mechanical drilling, or other means.

In an embodiment, the plurality of through holes 2000 can be straight, tapered, double tapered, or other hole shapes. The aperture diameter of each of the plurality of through holes 2000 is smaller than the diameter of the opening 200, such that a single opening 200 can accommodate two or more through holes 2000. For example, if the opening 200 has a diameter of 200 μm, the aperture diameter of each of the plurality of through holes 2000 can be from about 40 μm to about 100 μm, such as, for example, 40 μm, 50 μm, 60 μm, 70 μm, 80 μm, 90 μm, or 100 μm, but not limited thereto, and can be adjusted depending on the design requirements. In addition, the arrangement and the hole spacing of the plurality of through holes 2000 in the openings 200 can also be set according to the design.

As shown in FIG. 2D-1, metal (e.g., copper) is plated on the surfaces of the first insulating layer 21 on the first side 20a and the second side 20b of the core board body 20 and in the plurality of through holes 2000 to form a plurality of conductive pillars 232 in the plurality of through holes 2000, and a patterning process is subsequently carried out on the first insulating layer 21 on the two opposite sides of the core board body 20. The metal (e.g., copper) is patterned to form a circuit layer 231, and the conductive pillars 232 are electrically connected to the circuit layer 231. Accordingly, a circuit structure 23 is formed by the circuit layer 231 and the conductive pillars 232.

As shown in FIG. 2C-2 and FIG. 2D-2, a barrier layer 221 and a seed layer 222 can be formed on the surfaces of the first insulating layer 21 and the plurality of through holes 2000 to ensure good connection of the conductive paths on the two opposite sides of the core board body 20 and to enhance the bonding force between the plated metal (e.g., copper) and the first insulating layer 21 in the subsequent manufacturing process. Next, the circuit layer 231 and the conductive pillars 232 are formed on the seed layer 222 in conjunction with the electroplating and patterning process. Accordingly, the patterned barrier layer 221 and seed layer 222 are formed between the first insulating layer 21 and the circuit layer 231 and between the first insulating layer 21 and the conductive pillar 232.

In an embodiment, the barrier layer 221 and the seed layer 222 can be formed by sputtering, physical vapor deposition (PVD), chemical vapor deposition (CVD), or atomic layer deposition (ALD). The barrier layer 221 can be a conductive barrier layer or a dielectric barrier layer. The conductive barrier layer is made of tantalum, titanium nitride, tantalum nitride, tungsten nitride, or other metallic nitrides, but not limited thereto; and the dielectric barrier layer is made of silicon nitride, silicon nitrogen oxide, silicon carbon-nitride, or diamond-like carbon (DLC), but not limited thereto. The seed layer 222 is made of copper, manganese doped with copper, or ruthenium, but not limited thereto.

As shown in FIG. 2E, a wiring structure 24 is formed on the circuit structure 23 and electrically connected to the circuit structure 23.

In an embodiment, the wiring structure 24 includes at least one wiring layer 241, at least one second insulating layer 242, and a plurality of conductive blind vias 243 formed in the second insulating layer 242 and electrically connected to the wiring layer 241 and the circuit structure 23. For example, the wiring structure 24 can be made by electroplating a metal (e.g., copper) by a build-up process or other means. The second insulating layer 242 is made of an Ajinomoto build-up film (ABF) or other insulating materials, and the second insulating layer 242 can be made of the same or different material than the first insulating layer 21.

As shown in FIG. 2F, a solder resist layer 25 can be formed on the outermost side of the wiring structure 24, and at least a portion of the wiring layer 241 is exposed from the solder resist layer 25 to form an electrical connection pad 244 as an external contact.

Therefore, in the manufacturing method of the present disclosure, the large-size openings 200 are first manufactured in the substrate, and the small-size through holes 2000 are subsequently manufactured in the openings 200. Unlike the conventional manufacturing method of forming through holes in the substrate, the manufacturing method of the present disclosure is to form the through holes 2000 in the first insulating layer 21 made of an ABF in the openings 200 to manufacture conductive pillars, thereby greatly enhancing the capability of manufacturing small aperture diameter through holes and fine circuit structures and facilitating the development of high-density and high-precision package substrates.

Moreover, the package substrate of the present disclosure can be slotted in the area where high-density design is required locally, and fine line width/line spacing (L/S) circuits in the openings 200 are subsequently manufactured to form a localized high-density circuit structure in conjunction with the FCBGA design, which is conducive to the high input/output (I/O) density of the advanced packaging, improves the efficiency in the utilization of space, and effectively promotes the miniaturization of the package structure.

Further, the manufacturing method of the present disclosure has high flexibility, and the openings 200 can be selected in any shape such as rectangular, square, circular and elliptic according to the layout location, and the sizes of the openings 200 and the aperture diameter of the through holes 2000 in the openings 200 can be adjusted according to the circuit design so as to meet the needs of various package designs.

In addition, compared to the conventional manufacturing method which can only form a plurality of through holes of a single specification in the substrate, the present disclosure is to form a plurality of through holes 2000 in a single opening 200, allowing the specifications of the through holes 2000 in different openings 200 to be configured according to the local requirements, thereby ensuring a high degree of flexibility in the design of the substrate and a wide range of adaptability at the packaging stage.

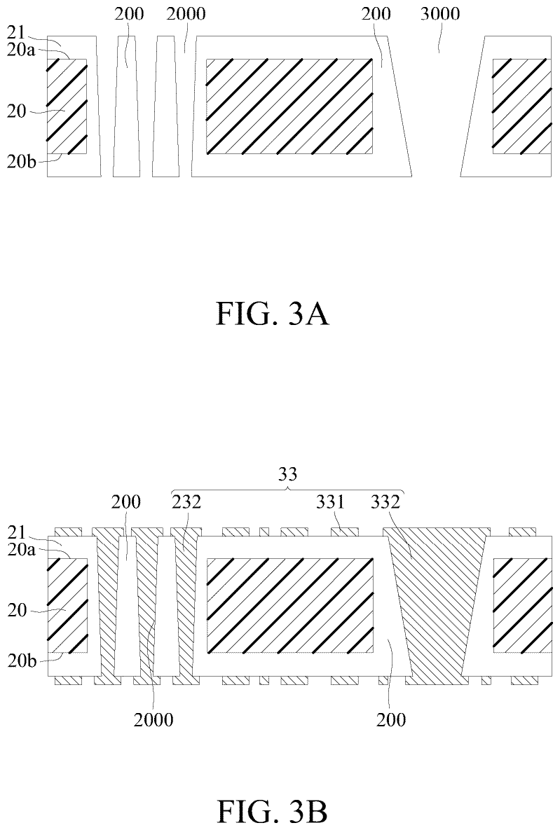

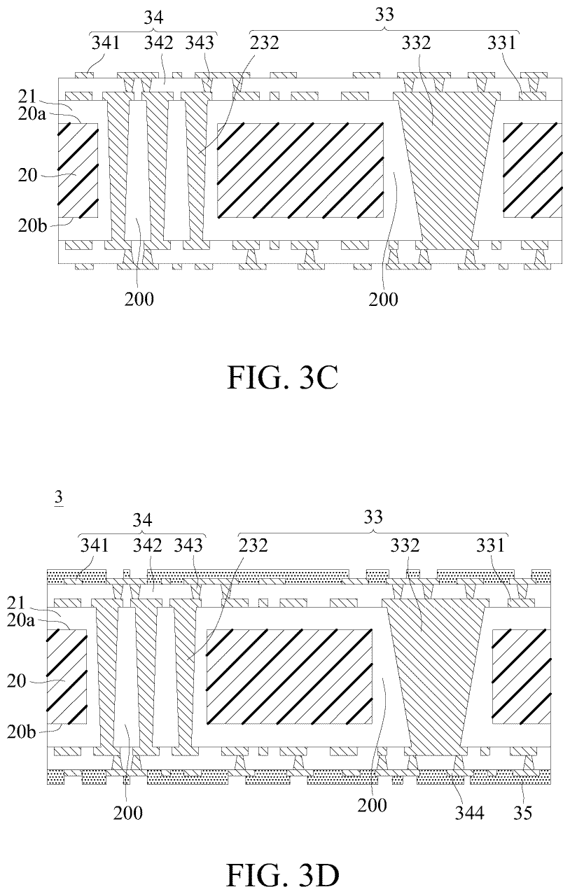

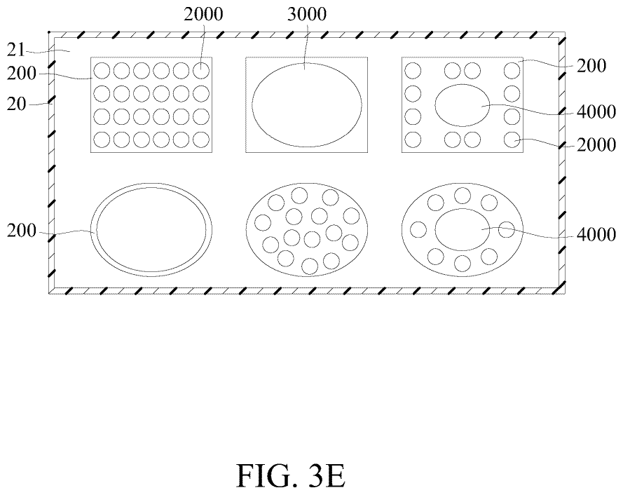

FIG. 3A to FIG. 3D are schematic cross-sectional views showing a manufacturing method of a package substrate 3 according to a second embodiment of the present disclosure. The difference between the second embodiment and the first embodiment is in the aperture diameter and number of through holes 3000, while the other manufacturing processes are generally the same, such that the similarities will not be repeated hereinafter.

As shown in FIG. 3A, a plurality of through holes 2000 and a single through hole 3000 connecting the first side 20a and the second side 20b of the core board body 20 are formed in the first insulating layer 21 of the plurality of openings 200, respectively. The aperture diameter of each of the plurality of through holes 2000 is smaller than the aperture diameter of the through hole 3000, and both the plurality of through holes 2000 and the through hole 3000 are connected to the surfaces of the first insulating layer 21 of the first side 20a and the second side 20b of the core board body 20.

In an embodiment, the plurality of through holes 2000 and the through hole 3000 can be straight, tapered, double tapered, or other hole shapes, and the hole shapes of the plurality of through holes 2000 and the through hole 3000 can be the same or different. The aperture diameter, number, arrangement and spacing of the plurality of through holes 2000 and the through hole 3000 in the single opening 200 can be adjusted according to the design requirements. Referring to the top view of FIG. 3E, the plurality of small aperture diameter through holes 2000 can be formed in a single opening 200, and a single large aperture diameter through hole 3000 can also be formed in a single opening 200, or even different sizes of through holes can be formed in a single opening 200. For example, a composite through-hole pattern of a medium aperture diameter through hole 4000 and at least one small aperture diameter through hole 2000 or a plurality of small aperture diameter through holes 2000 can be formed in a single opening 200, and corresponding conductive pillars can be formed therein.

As shown in FIG. 3B, metal (e.g., copper) is plated on the surfaces of the first insulating layer 21 on the first side 20a and the second side 20b of the core board body 20 and in the plurality of through holes 2000 to form a plurality of conductive pillars 232, 332 in the plurality of through holes 2000 and in the single through hole 3000. The diameter of the conductive pillar 332 is larger than the diameter of each of the conductive pillars 232, and a patterning process is subsequently carried out on the first insulating layer 21 on the two opposite sides of the core board body 20. The metal (e.g., copper) is patterned to form a circuit layer 331, and the conductive pillars 232, 332 are electrically connected to the circuit layer 331. Accordingly, a circuit structure 33 is formed by the circuit layer 331 and the conductive pillars 232, 332.

In addition, a barrier layer and a seed layer (not shown) can be formed on the surfaces of the first insulating layer, the plurality of through holes and the single through hole, as in the first embodiment, to ensure a good connection of the conductive paths on the two opposite sides of the core board body and to strengthen the bonding force between the plated metal (e.g., copper) and the first insulating layer in the subsequent manufacturing process. Next, the circuit layer and the conductive pillars are formed on the seed layer in conjunction with the electroplating and patterning process. Accordingly, the patterned barrier layer and seed layer are formed between the first insulating layer and the circuit layer, and between the first insulating layer and the conductive pillar.

As shown in FIG. 3C, a wiring structure 34 is formed on the circuit structure 33 and is electrically connected to the circuit structure 33. The wiring structure 34 includes at least one wiring layer 341, at least one second insulating layer 342, and a plurality of conductive blind vias 343 formed in the second insulating layer 342 and electrically connected to the wiring layer 341 and the circuit structure 33. For example, a build-up process is used to manufacture the wiring structure 24 by electroplating metal (e.g., copper) or other means.

As shown in FIG. 3D, a solder resist layer 35 can be formed on the outermost side of the wiring structure 34, and at least a portion of the wiring layer 341 is exposed from the solder resist layer 35 to form an electrical connection pad 344 as an external contact.

Therefore, in the manufacturing method of the present disclosure, the large-size openings 200 are first manufactured in the substrate, and the through holes 2000, 3000, 4000 are subsequently manufactured in the openings 200. Unlike the conventional manufacturing method of forming through holes in the substrate, the manufacturing method of the present disclosure is to form the through holes 2000, 3000, 4000 in the first insulating layer 21 made of an ABF in the openings 200 to manufacture conductive pillars 232, 332, thereby enhancing the capability of manufacturing small aperture diameter through holes and fine circuit structures and facilitating the development of high-density and high-precision package substrates.

Moreover, the package substrate of the present disclosure can be slotted in the area where high-density design is required locally, and fine line width/line spacing (L/S) circuits in the openings 200 are subsequently manufactured to form a localized high-density circuit structure in conjunction with the FCBGA design, which is conducive to the high input/output (I/O) density of the advanced packaging, improves the efficiency in the utilization of space, and effectively promotes the miniaturization of the package structure.

Further, the manufacturing method of the present disclosure has high flexibility, and the openings 200 can be selected in any shape such as rectangular, square, circular and elliptic in accordance with the layout location, and the sizes of the openings 200 and the aperture diameters of the through holes 2000, 3000, 4000 in the openings 200 can be adjusted according to the circuit design to meet the needs of various packaging designs.

In addition, compared to the conventional manufacturing method which can only form a plurality of through holes of a single specification in the substrate, the present disclosure is to form a plurality of through holes 2000 and a single through hole 3000 in the openings 200 respectively, allowing the specifications of the through holes 2000, 3000 in different openings 200 to be configured according to the local requirements, or the present disclosure can also form a composite plurality of through holes 2000, 4000 with the same or different aperture diameters in a single opening 200, thereby ensuring a high degree of flexibility in the design of the substrate and a wide range of adaptability at the packaging stage.

The present disclosure also provides a package substrate 2, 3. The package substrate 2, 3 comprises a core board body 20, a first insulating layer 21, a circuit structure 23, 33, and a wiring structure 24, 34.

The core board body 20 has a first side 20a and a second side 20b opposite to the first side 20a, and the core board body 20 is formed with a plurality of openings 200 connecting the first side 20a and the second side 20b of the core board body 20.

The first insulating layer 21 is formed on the first side 20a and the second side 20b of the core board body 20 and is filled into the openings 200, and the first insulating layer 21 of the openings 200 is formed with a plurality of through holes 2000, 3000, 4000 connected to surfaces of the first insulating layer 21 on the first side 20a and the second side 20b of the core board body 20.

The circuit structure 23, 33 includes a circuit layer 231, 331 formed on the surfaces of the first insulating layer 21 on the first side 20a and the second side 20b of the core board body 20, and a plurality of conductive pillars 232, 332 formed in the through holes 2000, 3000, 4000 respectively and electrically connected to the circuit layer 231, 331.

The wiring structure 24, 34 includes at least one wiring layer 241, 341, at least one second insulating layer 242, 342, and a plurality of conductive blind vias 243, 343 formed in the second insulating layer 242, 342 and electrically connected to the wiring layer 241, 341 and the circuit structure 23, 33.

In an embodiment, the core board body 20 can be made of glass, ceramic, silicon carbide (SiC), or a composite material with a modulus of 50 Gpa to 100 Gpa.

In an embodiment, the first insulating layer 21 and the second insulating layer 242, 342 include an Ajinomoto build-up film (ABF).

In an embodiment, a barrier layer 221 and a seed layer 222 are formed on the surfaces of the first insulating layer 21 and the surfaces of the plurality of through holes 2000, 3000, 4000, such that the barrier layer 221 and the seed layer 222 are located between the first insulating layer 21 and the circuit structure 23, 33.

In an embodiment, each of the openings 200 includes at least one shape independently selected from a group consisting of rectangular, square, circular and elliptical shapes.

In an embodiment, two or more through holes 2000 are formed in each single opening of the openings 200.

In an embodiment, a solder resist layer 25, 35 is formed on the wiring structure 24, 34, and at least a portion of the wiring layer 241, 341 is exposed from the solder resist layer 25, 35.

In summary, in the package substrate and manufacturing method thereof of the present disclosure, a high rigidity substrate with low warpage is used, and the through holes are formed in the insulating layer in the openings to manufacture conductive pillars, thereby greatly enhancing the capability of manufacturing small aperture diameter through holes and fine circuit structures and facilitating the development of high-density and high-precision package substrates.

In addition, the package substrate of the present disclosure can be slotted in the area where high density design is required locally, and fine line width/line spacing (L/S) circuits in the openings are subsequently manufactured to form a localized high-density circuit structure in conjunction with the FCBGA design, which is conducive to the high input/output (I/O) density of the advanced packaging, improves the efficiency in the utilization of space, and effectively promotes the miniaturization of the package structure.

Furthermore, the manufacturing method of the present disclosure has high flexibility, and the openings can be selected in any shape such as rectangular, square, circular and elliptic in accordance with the layout location, and the sizes of the openings and the aperture diameter of the through holes in the openings can be adjusted according to the circuit design, which can ensure good signal conduction in the inner layer of the substrate and save space at the same time and meet the needs of various package designs.

In addition, compared to the conventional manufacturing method which can only form a plurality of through-holes of a single specification in the substrate, the present disclosure is to form a plurality of through holes in a single opening, allowing the through-hole specifications in different openings to be configured according to the local requirements, or the present disclosure can also form a composite plurality of through holes with the same or different aperture diameters and aperture spacings in a single opening, thereby ensuring a high degree of flexibility in the design of the substrate and a wide range of adaptability at the packaging stage.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core board body having a first side and a second side opposite to the first side and including a plurality of openings connecting the first side and the second side of the core board body;
a first insulating layer formed on the first side and the second side of the core board body and filled into the plurality of openings, wherein a plurality of through holes are formed in the first insulating layer of the plurality of openings and are connected to surfaces of the first insulating layer on the first side and the second side of the core board body;
a circuit structure including a circuit layer formed on the surfaces of the first insulating layer on the first side and the second side of the core board body, and a plurality of conductive pillars formed in the plurality of through holes respectively and electrically connected to the circuit layer; and
a wiring structure formed on the circuit structure and including at least one wiring layer, at least one second insulating layer, and a plurality of conductive blind vias formed in the second insulating layer and electrically connected to the wiring layer and the circuit structure.

2. The package substrate of claim 1, wherein the core board body is made of glass, ceramic, silicon carbide, or a composite material with a modulus of 50 Gpa to 100 Gpa.

3. The package substrate of claim 1, wherein the first insulating layer and the second insulating layer are each made of an Ajinomoto build-up film.

4. The package substrate of claim 1, further comprising a barrier layer and a seed layer formed on the surfaces of the first insulating layer and surfaces of the plurality of through holes and located between the first insulating layer and the circuit structure.

5. The package substrate of claim 1, wherein each of the plurality of openings has at least one shape independently selected from a group consisting of rectangular, square, circular and elliptical shapes.

6. The package substrate of claim 1, wherein two or more of the plurality of through holes are formed in each single opening of the plurality of openings.

7. The package substrate of claim 1, further comprising a solder resist layer formed on the wiring structure, wherein a portion of the wiring layer is exposed from the solder resist layer.

8. A method of manufacturing a package substrate, comprising:
providing a core board body having a first side and a second side opposite to the first side;
forming a plurality of openings connecting the first side and the second side of the core board body;
forming a first insulating layer on the first side and the second side of the core board body and filling the first insulating layer into the plurality of openings;
forming a plurality of through holes in the first insulating layer of the plurality of openings, wherein the plurality of through holes are connected to surfaces of the first insulating layer on the first side and the second side of the core board body;
forming a circuit layer on the surfaces of the first insulating layer on the first side and the second side of the core board body, and forming a plurality of conductive pillars electrically connected to the circuit layer in the plurality of through holes, wherein the circuit layer and the plurality of conductive pillars constitute a circuit structure; and
forming a wiring structure on the circuit structure, wherein the wiring structure includes at least one wiring layer, at least one second insulating layer, and a plurality of conductive blind vias formed in the second insulating layer and electrically connected to the wiring layer and the circuit structure.

9. The method of claim 8, wherein the core board body is made of glass, ceramic, silicon carbide, or a composite material with a modulus of 50 Gpa to 100 Gpa.

10. The method of claim 8, wherein the first insulating layer and the second insulating layer are each made of an Ajinomoto build-up film.

11. The method of claim 8, further comprising prior to forming the circuit structure, forming a barrier layer and a seed layer on the surfaces of the first insulating layer and surfaces of the plurality of through holes, wherein the barrier layer and the seed layer are located between the first insulating layer and the circuit structure.

12. The method of claim 8, wherein each of the plurality of openings has at least one shape independently selected from a group consisting of rectangular, square, circular and elliptical shapes.

13. The method of claim 8, wherein two or more of the plurality of through holes are formed in each single opening of the plurality of openings.

14. The method of claim 8, further comprising forming a solder resist layer on the wiring structure, wherein a portion of the wiring layer is exposed from the solder resist layer.
